(19) United States
(12) Patent Application Publication
(10) Pub. No.: US 2008/0164487 A1
(43) Pub. Date: Jul. 10, 2008

(54) CERAMIC PACKAGE FOR LED

(75) Inventors: Hsin-Chun LIU, Hsin-Tien City (TW); Yao-I WANG, Hsin-Tien City (TW); Chih-Liang SU, Hsin-Tien City (TW); Fang-Po WANG, Hsin-Tien City (TW)

Correspondence Address: LOWE HAUPTMAN HAM & BERNER, LLP, 1700 DIAGONAL ROAD, SUITE 300, ALEXANDRIA, VA, 22314, US

(73) Assignee: LEDTECH ELECTRONICS CORP., Hsin-Tien City (TW)

(21) Appl. No.: 11/675,264

(22) Filed: Feb. 15, 2007

(30) Foreign Application Priority Data
Jan. 8, 2007 (TW) 096100612

(51) Int. Cl. H01L 33/00; H01L 21/00

(52) U.S. Cl. 257/99; 257/100; 438/22; 257/E33.058

(57) ABSTRACT

A ceramic light emitted diode (LED) package has a pair of discrete reflection walls to reflect light emission from the LED. With two opposite reflection walls and two opposite openings around the LED, light emitted from the LED package can be fanned out.

### RELATED APPLICATIONS

The present application is based on, and claims priority from, Taiwan application Serial Number 096,100,612, filed on Jan. 8, 2007, the disclosure of which is hereby incorporated by reference herein in its entirety.

### TECHNICAL FIELD

This disclosure relates to ceramic package for LED, especially for a LED that fans out its light emission.

### BACKGROUND

FIG. 1 Prior art.

China Patent Publication CN1,588,652 discloses a ceramic package for light emitted diode (LED). A LED 12 is mounted on a first ceramic substrate 11. The first ceramic substrate 11 has a top metal area (not shown), a bottom metal area (not shown), and vertical half through holes 131 with metal on its wall. The metal wall couples the top metal area to the bottom metal area. The bottom metal areas are made for surface mount of the package. A second ceramic substrate 14 has an opening 141, the second ceramic substrate 14 is laminated on the first ceramic substrate 11. The opening 141 is for the accommodation of the diode 12.

FIG. 2 is a section view of FIG. 1 along AA′.

The first ceramic substrate 11 has a first metal area 111 and a second metal area 112 on its first side or top side, and a third metal area 113 and a fourth metal area 114 on its second side or bottom side. A first vertical connecting hole wall metal 131 couples the first metal area 111 to the third metal area 113, and A second vertical connecting hole wall metal 132 couples the second metal area 112 to the fourth metal area 114. A LED 12 mounts on the second metal area 112. The LED 12 has a top electrode wire bonding to the first metal area 111 through bonding wire 13. The LED 12 has a bottom electrode coupling to the second metal area 112 through direct contact bonding with electric conductive glue. The second ceramic substrate 14 has a hollow area 141, laminated on top of the first ceramic substrate 11. The hollow area 141 is for the accommodation of the LED diode 12. The first metal area 111 electrically couples to the third metal area 113 through the first vertical connecting hole wall metal 131. The second metal area 112 electrically couples to the fourth metal area 114 through the second vertical connecting hole wall metal 132.

### SUMMARY

This invention discloses a LED mounted on a ceramic substrate, the top ceramic substrate has a pair of reflection walls to reflect the light from the LED. In an aspect, opposite open sides in combination with opposite reflection walls fans out the light emission of the LED.

### BRIEF DESCRIPTION OF THE DRAWINGS

FIG. 1 shows a Prior Art device.

FIG. 2 shows a section view of FIG. 1 taken along line A-A′

FIG. 3˜FIG. 7 show the manufacturing process in accordance with an embodiment of this invention.

FIG. 8 shows an elevation view of a typical unit in accordance with an aspect of this invention.

FIG. 9A shows an elevation view of a first embodiment unit of this invention.

FIG. 9B shows an elevation view of a second embodiment unit of this invention.

FIG. 9C shows an elevation view of a third embodiment unit of this invention.

FIG. 10A shows an elevation view of a first embodiment multi-unit of this invention.

FIG. 10B shows an elevation view of a second embodiment multi-unit of this invention.

FIG. 10C shows an elevation view of a third embodiment multi-unit of this invention.

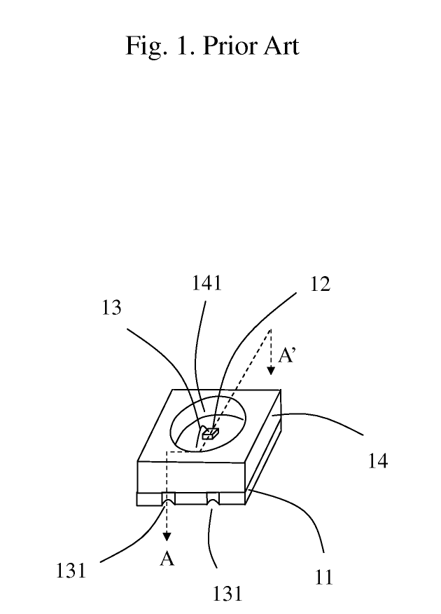

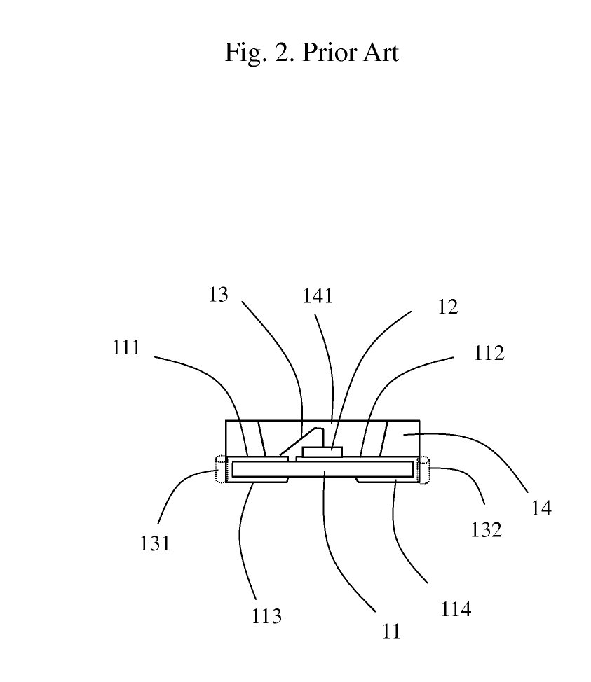

### DETAILED DESCRIPTION OF EMBODIMENTS

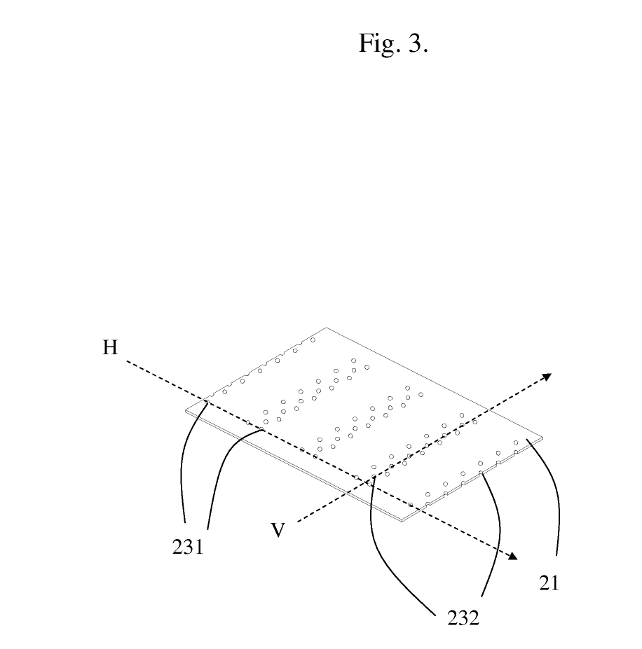

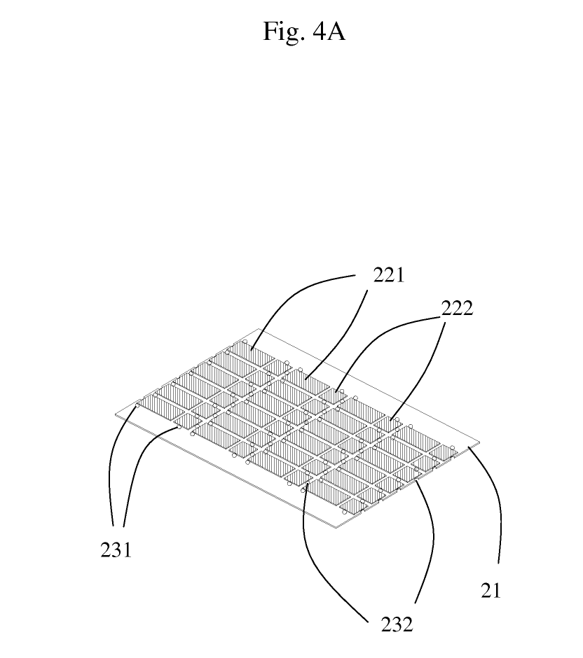

FIG. 3˜FIG. 7 show the manufacturing process in accordance with an embodiment of this invention.

FIG. 3 shows firstly to prepare a first ceramic substrate 21, the first ceramic substrate 21 comprises: a first plurality of through holes 231 along a horizontal line H, a second plurality of through holes 232 along a vertical line V.

FIG. 4A shows the top side of the ceramic substrate 21 and the step of forming a first metal area 221 and a second metal area 222 on a first side of the first ceramic substrate 21. The metal areas 221 and 222 electrically couple to the neighboring through holes 231 and 232. Each of the through holes 232 and 231 is made to have its wall metallized, or alternatively filled with metal material to form a conductor.

FIG. 4B shows the bottom side of the first ceramic substrate 21 and the step of forming a third metal area 223 and a fourth metal area 224 on a second side of the first ceramic substrate 21. The metal areas 223 and 224 electrically couple to the neighboring through holes 231 and 232 so that the first metal 221 electrically couples to the third metal area 223, and the second metal area 222 electrically couples to the fourth metal area 224 through the metal in the through holes 231 and 232.

FIG. 5 shows a second ceramic substrate 24 and the step of preparing a second ceramic substrate 24. The second ceramic substrate 24 is then laminated on said first ceramic substrate 21. The second ceramic substrate 24 has an open area 241. The open area 241 has reflection walls on its periphery. The open area 241 reveals part of the first metal area 221 and part of the second area 222.

FIG. 6 shows how LEDs are mounted and the step of preparing a plurality of LEDs 22, each mounted on the first metal area 221. Each LED 22 has two top electrodes as an example in this figure, i.e., the first and second surface electrodes, which are then coupled to the first metal area 221 and the second metal area 222 respectively through bonding wires 23. If the LED 22 has two bottom electrodes, flip-chip bonding can be used for coupling the bottom electrodes to the first metal 221 and the second metal 222. If the LED 22 has a top surface electrode and a bottom electrode, then the top electrode can be connected by a bonding wire to the second metal area 222, and the bottom electrode couples to the first metal area 221 through direct metal contact when the LED is mounted on the first metal area 221. After cutting the laminated structure as shown in FIG. 6, a pair of reflection walls are formed in the package for LED 22 to reflect light emission from the LED. In combination with the opposite openings the light emission fans out of the package. Transparent glue 25 can be applied in the open area 241 to protect the LED chip 22 and bonding wire 23.

FIG. 7 shows the cutting process. Cutting along horizontal lines H yields a plurality of light units in serial connection 71. Cutting along vertical lines V yields a plurality of light units in parallel connection 72. Cutting along horizontal lines H and then cutting along vertical lines V yield a plurality of single light units 73. In some cases, when the light unit is mounted on a mother board laterally so as to result in light emission parallel with the mother board, the third metal area 223, the fourth metal area 224, and the through holes 231 and 232 can be omitted.

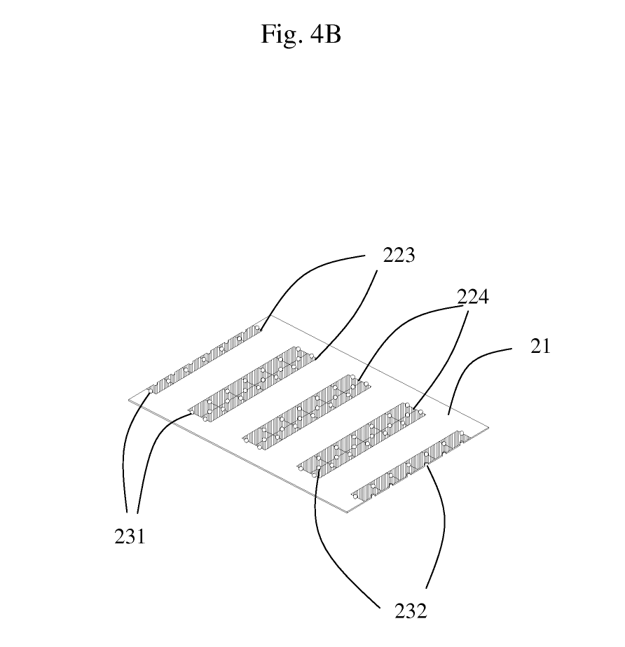

FIG. 8 shows a perspective view of a typical product in accordance with an aspect of this invention. The light unit has a first ceramic substrate 21, the ceramic substrate 21 has a first side or top side on which a first metal area 221 and a second metal area 222 are located. The ceramic substrate 21 has a second side or bottom side, on which a third metal area 223 and a fourth metal area 224 are located.

The first metal area 221 is coupled to the third metal area 223 through the connecting metal in through holes 231 or 232 and the second metal area 222 is coupled to the fourth metal area 224 through the connecting metal in holes 231 or 232.

A second ceramic substrate 24 is prepared and laminated on the first ceramic substrate 21. The second ceramic substrate 24 has a pair of discrete reflection walls 2411 and 2412 in a typical single light unit; and the LED 22 is arranged between the two reflection walls 2411 and 2412 so that the light emission from the LED 22 can be reflected by the slanted reflection walls 2411 and 2412. The LED 22 is mounted on the first metal area 221, and has two top surface electrodes respectively coupled to the first metal area 221 and the second metal area 222. Transparent glue fills in between the two reflection walls 2411 and 2412 to protect the LED 22 and bonding wire 23. There are opposite open areas and opposite reflection walls around the LED 22, the light emitted from the LED 22 is thereby shaped and fanned out.

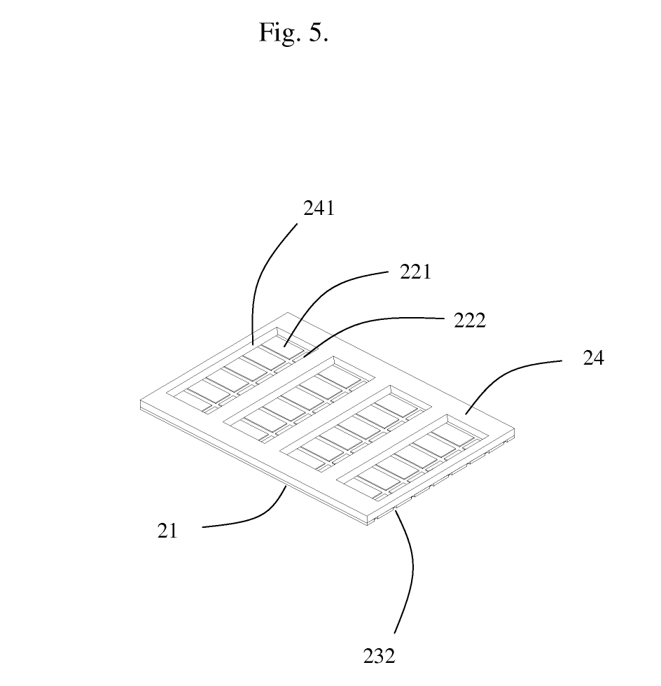

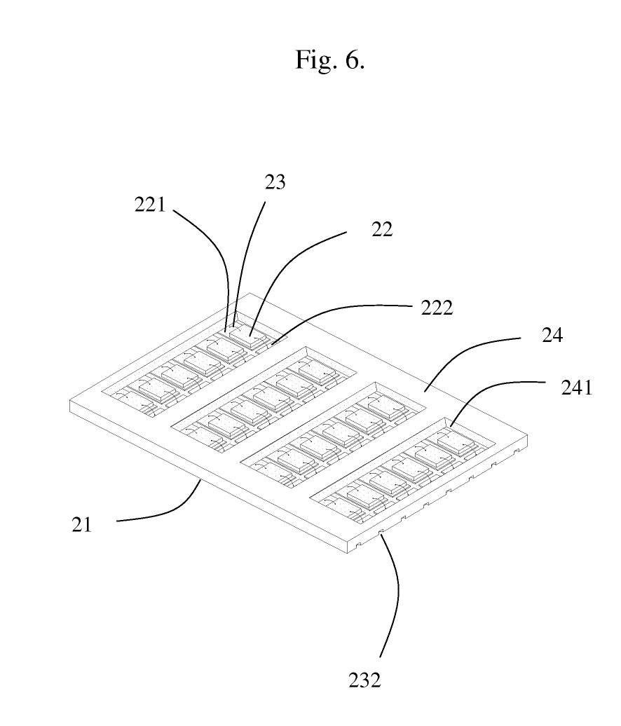

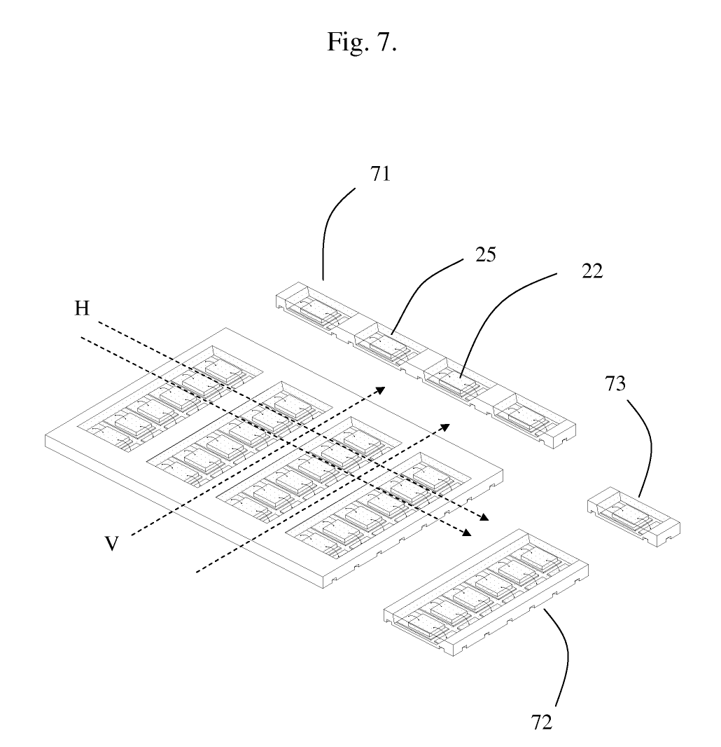

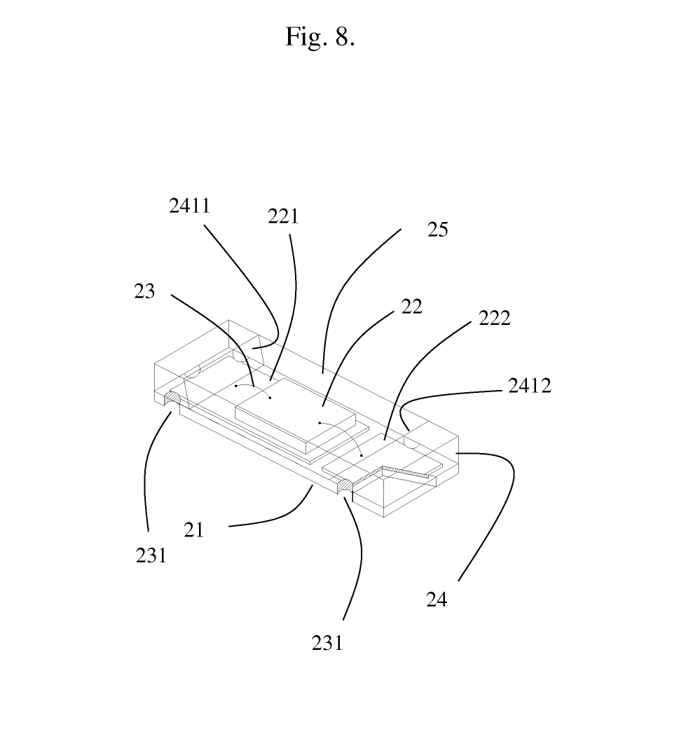

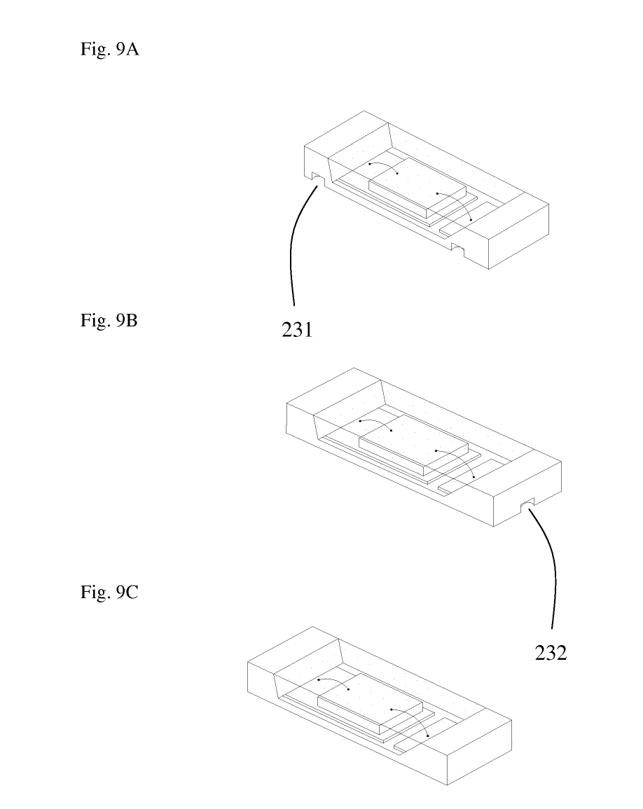

FIG. 9A shows a first single light unit embodiment of the present invention. If the first plurality of through holes 231 are arranged on the horizontal cutting lines H, and meanwhile the second plurality of through holes 232 are not arranged on the vertical cutting lines V, then, after cutting along the horizontal lines H and cutting the vertical lines V, a plurality of single light unit as shown in FIG. 9A are obtained.

FIG. 9B shows a second single light unit embodiment of the present invention. If the first plurality of through holes 231 are not arranged on the horizontal cutting lines H, and meanwhile the second plurality of through holes 232 are arranged on the vertical cutting lines V, then, after cutting along the horizontal lines H and cutting the vertical lines V, a plurality of single light unit as shown in FIG. 9B are obtained.

FIG. 9C shows a third single light unit embodiment of the present invention. If the first plurality of through holes 231 are not arranged on the horizontal cutting lines H, and meanwhile the second plurality of through holes 232 are not arranged on the vertical cutting lines V, then, after cutting along the horizontal lines H and cutting the vertical lines V, a plurality of the single light unit as shown in FIG. 9C are obtained.

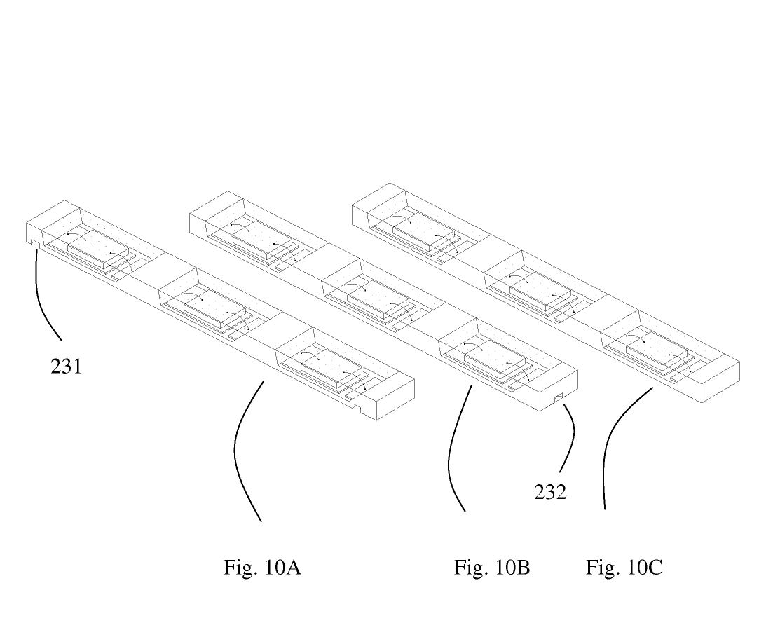

FIG. 10A shows a first serially connected light units embodiment of the present invention. If the first plurality of through holes 231 are arranged on the horizontal cutting lines H, and meanwhile the second plurality of through holes 232 are not arranged on the vertical cutting lines V, then, after cutting along the horizontal lines H and cutting the vertical lines V, a plurality of serially connected light units as shown in FIG. 10A are obtained.

FIG. 10B shows a second serially connected light units embodiment of the present invention. If the first plurality of through holes 231 are not arranged on the horizontal cutting lines H, and meanwhile the second plurality of through holes 232 are arranged on the vertical cutting lines V, then, after cutting along the horizontal lines H and cutting the vertical lines V, a plurality of serially connected light units as shown in FIG. 10B are obtained.

FIG. 10C shows a third serially connected light units embodiment of the present invention. If the first plurality of through holes 231 are not arranged on the horizontal cutting lines H, and meanwhile the second plurality of through holes 232 are not arranged on the vertical cutting lines V, then, after cutting along the horizontal lines H and cutting the vertical lines V, a plurality of serially connected light units as shown in FIG. 10C are obtained.

While the embodiments have been described by way of example, it will be apparent to those skilled in the art that various modification may be made in the embodiments without departing from the spirit and scope of the present invention, as defined by the appended claims.

What is claimed is:

1. A ceramic LED package, comprising:
a first ceramic substrate comprising:
a first side having a first metal area and a second metal area;
a second side having a third metal area and a fourth metal area;
a first connecting metal coupling said first metal area to said third metal area; and
a second connecting metal coupling said second metal area to said fourth metal area;
a second ceramic substrate laminated on said first ceramic substrate and comprising a pair of discrete reflection walls; and
a light emitting diode (LED) mounted on said first ceramic substrate and having electrodes respectively coupled to said first metal area and said second metal area, said LED being mounted between said reflection walls.

2. A ceramic LED package as claimed in claim 1, wherein said coupling between at least one of the electrodes and the respective metal area is wire bonding.

3. A ceramic LED package as claimed in claim 1, wherein said coupling between at least one of the electrodes and the respective metal area is flip chip bonding.

4. A ceramic LED package as claimed in claim 1, wherein said reflection walls are inclined surfaces.

5. A ceramic LED package as claimed in claim 1, further comprising:
transparent glue sealed in between said walls.

6. A ceramic LED assembly, comprising multiple ceramic LED packages each being as claimed in claim 1, wherein said packages are serially connected.

7. A ceramic LED assembly, comprising multiple ceramic LED packages each being as claimed in claim 1, wherein said packages are connected in parallel.

8. A ceramic LED package as claimed in claim 1, wherein at least one of said connecting metals is a metal wall of a through hole.

9. A ceramic LED package as claimed in claim 1, wherein at least one of said connecting metals is a metal-filled through hole.

10. A ceramic LED package as claimed in claim 1, wherein said first connecting metal is located at an edge of said first ceramic substrate.

11. A ceramic LED package as claimed in claim 1, wherein said second connecting metal is located at an edge of said first ceramic substrate.

12. A method of manufacturing a ceramic LED package, said method comprising:
preparing a first ceramic substrate, said first ceramic substrate comprising:
a first side having a first metal area and a second metal area;
a second side having a third metal area and a fourth metal area;
a first connecting metal coupling said first metal area to said third metal area; and
a second connecting metal coupling said second metal area to said fourth metal area;
laminating a second ceramic substrate on said first ceramic substrate, said second ceramic substrate comprising a pair of discrete reflection walls; and
mounting a light emitting diode (LED) on said first ceramic substrate so that electrodes of said LED are respectively coupled to said first metal area and said second metal area;
wherein said LED is mounted between said reflection walls.

13. The method as claimed in claim 12, further comprising:
a transparent glue sealing process to protect said LED.

14. The method as claimed in claim 12, wherein at least one of said connecting metals is a metal wall of a through hole.

15. The method as claimed in claim 12, wherein at least one of said connecting metals is a metal filled in a through hole.

16. The method as claimed in claim 12, further comprising:
a cutting process to obtain a plurality of serially connected packages.

17. The method as claimed in claim 12, further comprising:
a cutting process to obtain a plurality of packages connected in parallel.

18. The method as claimed in claim 16, wherein said cutting process comprises cutting along said first connecting metal.

19. The method as claimed in claim 16, wherein said cutting process comprises cutting along said second connecting metal.
